(19) United States
(12) Patent Application Publication
(10) Pub. No.: US 2022/0046361 A1
(43) Pub. Date: Feb. 10, 2022

(54) MOBILE DEVICE HAVING A TUBULAR MICROPHONE INTEGRATED INTO A COVER ASSEMBLY

(71) Applicant: Apple Inc., Cupertino, CA (US)

(72) Inventors: Jared P. Ostdiek, San Francisco, CA (US); Brandon R. Collins-Smoot, Campbell, CA (US)

(21) Appl. No.: 16/988,560

(22) Filed: Aug. 7, 2020

(51) Int. Cl. H04R 19/04; H04M 1/03; H04M 1/02; H04R 1/04; H04R 1/08; B81B 7/00

(52) U.S. Cl. CPC H04R 19/04; H04M 1/035; H04M 1/0264; H04M 1/0283; H04R 1/04; H04R 1/086; B81B 2207/012; H04M 2250/52; H04R 2201/003; H04R 2499/11; H04R 2499/15; B81B 2201/0257; B81B 7/0058

(57) ABSTRACT

A mobile device may include an enclosure and a rear cover assembly affixed to a back portion of the enclosure. The rear cover assembly may include a protruding portion that extends above a surrounding portion of the rear cover assembly. The protruding portion may include a number of through holes that extend through the protruding portion of the rear cover assembly. In one through hole, a tubular microphone may be provided. The tubular microphone may include a microphone enclosure which may contain a MEMS microphone device, an integrated circuit, and an interposer positioned between the MEMS microphone device and the integrated circuit. A height of the tubular microphone may be substantially similar to a thickness of the protruding portion and the tubular microphone may be entirely or partially disposed within a through hole of the protruding portion.

### TECHNICAL FIELD

Embodiments described herein relate generally to microphone assemblies and mobile device enclosures that receive and couple microphone assembles to a mobile device. More particularly, the present embodiments relate to tubular microphone assemblies, cover assemblies, and enclosures for mobile devices.

### BACKGROUND

Modern mobile device may include various acoustic components including microphones and speakers. However, traditional packaging techniques and form factors make it difficult to incorporate these types of devices in exceedingly thin devices in which interior volume is limited. The systems and techniques described herein are directed to microphone packaging and integration techniques that do not have some of the drawbacks associated with traditional microphone packaging solutions.

### SUMMARY

In some embodiments, a mobile device may comprise a touch-sensitive display. The mobile device may further comprise an enclosure at least partially surrounding the touch-sensitive display. The mobile device may additionally comprise a glass component coupled to the enclosure and defining a hole that extends through the glass component. The mobile device may further comprise a microphone assembly comprising a microphone enclosure positioned within the hole and coupled to the glass component. The microphone enclosure may define an acoustic port. The microphone assembly may additionally comprise a micro-electro-mechanical system (MEMS) microphone device positioned within the microphone enclosure and adjacent to the acoustic port, an integrated circuit positioned within the microphone enclosure, and an interposer positioned between the MEMS microphone device and the integrated circuit, the interposer operatively coupling the MEMS microphone device and the integrated circuit.

A glass component may further define a protruding portion and a base portion surrounding the protruding portion. The protruding portion may extend outward from the base portion and the hole may extend through the protruding portion of the glass component.

The protruding portion may have a first thickness greater than 1 mm and less than or equal to 2 mm. The base portion may have a second thickness greater than 0.5 mm and less than 1 mm. The microphone enclosure may have a height that is equal to or less than the first thickness.

The enclosure may define an internal cavity of the mobile device, a printed circuit board may be disposed within the internal cavity, and at least a portion of the microphone assembly may be operatively coupled to the printed circuit board. A support structure may additionally be coupled to the printed circuit board and may be configured to limit a bending of the protruding portion.

The glass component may define a rear surface of the mobile device. The microphone assembly may further comprise a wire mesh coupled to the microphone enclosure. In some embodiments, the wire mesh may be flush with the rear surface. A stiffener coupled to the wire mesh may be provided between the wire mesh and the microphone enclosure. An acoustic mesh may be coupled to the microphone enclosure and the stiffener and may be configured to inhibit an ingress of particles toward the MEMS microphone device.

In some embodiments, an interposer may have a u-shaped profile that partially surrounds a center region of the MEMS microphone device and the u-shaped profile of the interposer may allow at least a portion of a rear surface of the MEMS microphone device to vibrate in response to acoustic vibrations.

In some embodiments, a microphone assembly may comprise a microphone enclosure configured to engage with at least a portion of a cover of a mobile device and may define an acoustic port. A micro-electro-mechanical system (MEMS) microphone device may be positioned within the microphone enclosure and may be adjacent to the acoustic port. An integrated circuit may be positioned within the microphone enclosure. An interposer may be positioned between the MEMS microphone device and the integrated circuit, the interposer operatively coupling the MEMS microphone device and the integrated circuit.

The interposer may at least partially surround a portion of a rear surface of the MEMS microphone device and the interposer may comprise a set of electrically conductive columns that operatively couple the MEMS microphone device with the integrated circuit.

In some embodiments, the microphone enclosure may comprise a first portion having a first circumference and a second portion having a second circumference. The second circumference may be larger than the first circumference. The second portion of the microphone enclosure may be attached to with the cover. The microphone enclosure may comprise a flange and the flange may be attached to the ceramic component.

In some embodiments, a wire mesh may be coupled to the microphone enclosure and a stiffener may be coupled to the wire mesh. An acoustic mesh may be coupled to the microphone enclosure and the stiffener and may be configured to prevent particles from reaching the MEMS microphone device.

In some embodiments, a mobile device may comprise an enclosure. The enclosure may define a side surface of the mobile device. A rear cover assembly may be coupled to the enclosure. The rear cover member may define a base portion, a protruding portion extending from the base portion, and a hole extending through the protruding portion. The mobile device may additionally comprise a microphone assembly. The microphone assembly may comprise a microphone enclosure positioned within the hole and defining an acoustic port. The microphone assembly may further comprise a micro-electro-mechanical system (MEMS) microphone device positioned within the microphone enclosure and configured to receive acoustic signals through the acoustic port.

The microphone assembly may further comprise an integrated circuit positioned within the microphone enclosure and an interposer positioned between the MEMS microphone device and the integrated circuit. The interposer may operatively couple the MEMS microphone device and the integrated circuit.

In some embodiments, the rear cover assembly may be a glass rear cover assembly and a ratio between a first thickness of the protruding portion and a second thickness of the base portion may be from about 1.5 to about 2.5.

The protruding portion may define a front surface. The rear cover assembly may define a rear surface opposite from the front surface. The hole may extend from the front surface to the rear surface. A flex connector may be positioned over the rear surface of the rear cover assembly and may be operatively coupled to the microphone assembly. A top surface of the microphone assembly may be flush with the front surface of the protruding portion.

In some embodiments, the hole may be a first hole, the rear cover assembly may further comprises a second hole extending through the protruding portion, and a camera assembly may be at least partially positioned within the second hole. The camera assembly may be a first camera assembly. The rear cover assembly may further define a third hole extending through the protruding portion and a fourth hole extending through the protruding portion. A second camera assembly may be at least partially positioned within the third hole and an optical flash may be at least partially positioned within the fourth hole.

### BRIEF DESCRIPTION OF THE DRAWINGS

Reference will now be made to representative embodiments illustrated in the accompanying figures. It should be understood that the following descriptions are not intended to limit the embodiments to one preferred embodiment. To the contrary, it is intended to cover alternatives, modifications, and equivalents as may be included within the spirit and scope of the described embodiments as defined by the appended claims. Identical reference numerals have been used, where possible, to designate identical features that are common to the figures.

FIG. 1A illustrates an isometric view of a front portion of an example mobile device including microphone enclosures, as described herein.

FIG. 1B illustrates an isometric view of a back portion of the example mobile device including microphone enclosures of FIG. 1A, as described herein.

FIG. 2 illustrates a partial cross-sectional view of a mobile device including a microphone assembly, as described herein.

FIG. 3A illustrates an isometric view of a microphone assembly, as described herein.

FIG. 3B illustrates an exploded isometric view of the microphone assembly of FIG. 3A with internal components, as described herein.

FIG. 4A illustrates a partial cross-sectional view of a microphone assembly, as described herein.

FIG. 4B illustrates a partial cross-sectional view of a microphone assembly as installed in a microphone enclosure of a mobile device, as described herein.

FIG. 5A illustrates a partial cross-sectional view of a microphone assembly in a friction-fit arrangement in a microphone enclosure of a mobile device, as described herein.

FIG. 5B illustrates a partial cross-sectional view of a microphone assembly in a snap-fit arrangement in a microphone enclosure of a mobile device, as described herein.

FIG. 6 illustrates a partial cross-sectional view of a microphone assembly with a wire connector, as described herein.

FIGS. 7A-7D depict multiple examples of differently shaped micro-electromechanical system (MEMS) devices of a microphone assembly, as described herein.

FIGS. 8A-C depict multiple examples of differently shaped interposers of a microphone assembly, as described herein.

FIG. 9 depicts a block diagram of an example mobile device that can incorporate a microphone assembly, as described herein.

The use of cross-hatching or shading in the accompanying figures is generally provided to clarify the boundaries between adjacent elements and to facilitate legibility of the figures. Accordingly, neither the presence nor absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof), and the boundaries, separations, and positional relationships presented therebetween, are provided in the accompanying figures merely to facilitate an understanding of the various embodiments described herein, may not necessarily be presented or illustrated to scale, and are not intended to indicate any preference or requirement for an illustrated embodiment to the exclusion of embodiments described with reference thereto.

### DETAILED DESCRIPTION

The following disclosure relates to various apparatuses and techniques related to tubular microphone assemblies, microphone enclosures on a mobile device, and associated components thereof. A tubular microphone assembly may be manufactured to have a height substantially similar to a thickness of a rear component of a mobile device enclosure. The microphone assembly may fit within a hole formed in the rear component and may reduce or eliminate the presence of microphone components within an internal cavity of the mobile device enclosure. In some embodiments, the rear component may be a transparent or light transmissive rear component.

In some embodiments, a mobile device may have an enclosure made from one of or multiple of a variety of materials including metal, ceramic, wood, plastic, or glass. For example, an enclosure may be made partially of glass to provide structural stability and a desirable tactile feel to a user of the mobile device. Holes may be formed through various portion of the enclosure, including a rear component thereof, to incorporate input/output devices such as cameras, microphones, optical flashes, light emitting elements, speakers, power outlets, buttons, switches, biometric sensors, any combination thereof, and any other sensor or device. Some holes may formed across an entire thickness of the enclosure and some hole may be formed across a partial thickness of the enclosure.

In some embodiments, a microphone assembly may be positioned within one or number of holes and may have a height less than, equivalent to, or substantially equivalent to a height of the hole and a thickness of the rear enclosure. By positioning the microphone assembly within the hole itself, the microphone assembly may not need to be positioned within an internal cavity of the mobile device. In this way, space within the internal cavity may be saved for other components of the mobile device.

In some embodiments, a surface of the microphone assembly may be flush with portions of the enclosure. For example, the enclosure may include a rear surface with a hole. The microphone assembly may be positioned within the hole and may have a top surface that is flush with the immediately surrounding glass rear surface. In this way, sound received by the microphone assembly may avoid scattering which may occur within the hole if the microphone assembly were recessed, though in some embodiments such scattering may be minor and/or desirable. Additionally or alternatively, the feel and appearance of the flush microphone assembly may be desirable to a user. As used herein, the term “flush” may include embodiments where the surface of the microphone assembly is fully or substantially aligned with surface of the surrounding glass rear surface. In some embodiments, a microphone assembly considered to be flush may be recessed by less than about 0.05 mm with respect to the surrounding glass rear surface.

In some embodiments, a microphone assembly may include a microphone enclosure, and a microphone stack-up positioned within the microphone enclosure. The microphone stack-up may contain a micro-electro-mechanical system (MEMS) device, an integrated circuit, and an interposer positioned between the MEMS device and the integrated circuit. In some embodiments, the integrated circuit may be an application-specific integrated circuit (ASIC).

The components of the microphone stack-up may be vertically stacked to minimize a dimension of a horizontal component of the microphone assembly. The vertically stacked microphone stack-up may fit within a hole of an enclosure while minimizing any empty space. A portion of the MEMS device may, nevertheless, be disposed so as to not be in contact with any other element of the microphone stack-up. In this way, the portion of the MEMS device may vibrate in response to received sound.

In some embodiments, the microphone assembly may be constructed so as to be waterproof and/or to inhibit an ingress of particles toward the microphone assembly, by the form factor of the microphone assembly and associated filters and/or components.

In some embodiments, the microphone assembly may be proximate to other components within the mobile device, such as a speaker assembly, light emitting element, or a camera assembly which may extend from an internal cavity of the mobile device through a hole in an enclosure of the mobile device. The microphone assembly may be integrated with a camera, an array of cameras, a sensing array, or a sensing module within a single hole of the mobile device enclosure. In some embodiments, the microphone assembly may be disposed in a distinct hole near additional holes containing other electronic components, such as a camera, an array of cameras, a sensing array, or a sensing module.

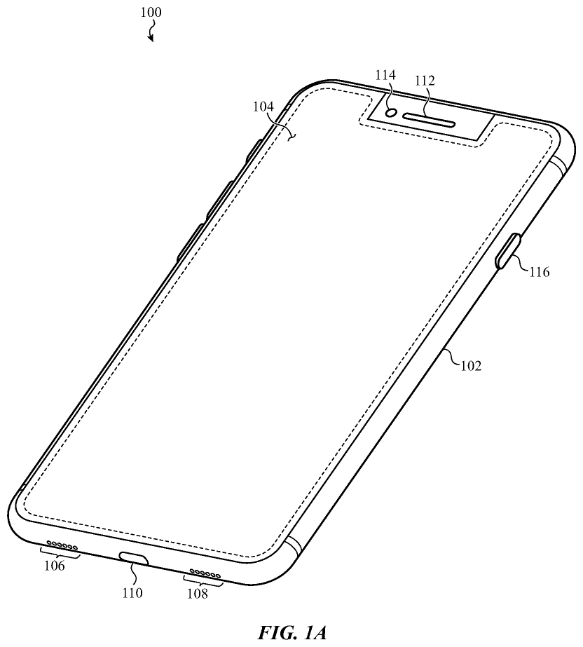

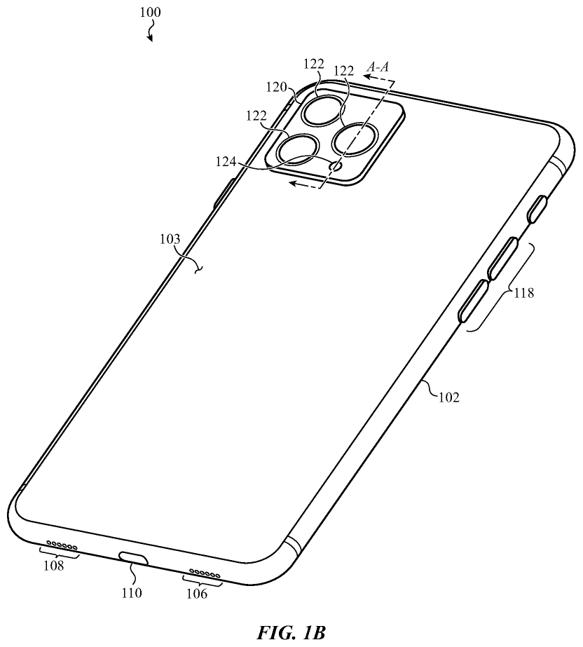

The discussion herein with respect to mobile device enclosures and microphone assemblies relate more generally to the disposition of a microphone assembly in relation to a mobile device enclosure. These and other embodiments are discussed with reference to FIGS. 1-9. However, those skilled in the art will readily appreciate that the detailed description given herein with respect to these figures is for explanatory purposes only and should not be construed as limiting.

FIG. 1A illustrates an isometric view of a front portion of an example mobile device 100 including a first microphone assemb1y106 and a second microphone assembly 114. The mobile device 100 may additionally include an enclosure 102 (e.g., a housing), a display 104 (e.g., a touch-sensitive display), a first speaker assemb1y108, a charging port 110, a second speaker assemblyl12, and a button 116. The enclosure 102 may at least partially surround the display 104. In some embodiments, a protective cover may be positioned over the display 104 and may define a transparent portion. The protective cover and/or the display 104 may be coupled to the enclosure 102 with an adhesive, a fastener, an engagement feature, and/or any combination thereof.

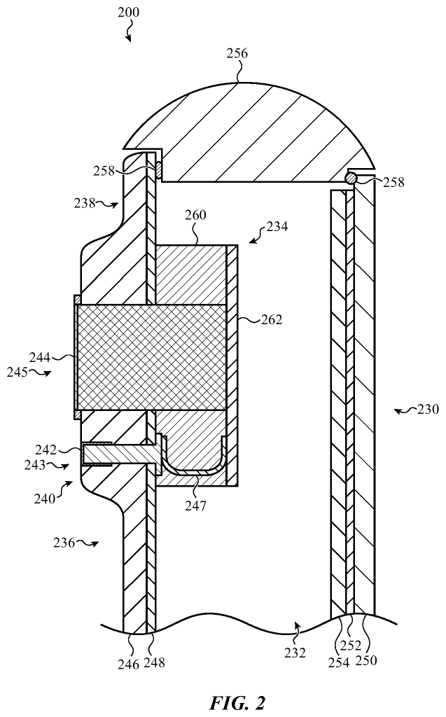

The enclosure 102 may at least partially define a front surface, a side surface, and a rear surface of the mobile device 100 and may include one or more metal members, one or more ceramic members, one or more plastic members, one or more glass members, and the like (see FIG. 1B). In this example, a transparent cover positioned over the display 104 defines a front surface of the mobile device 100 and the enclosure 102 defines four sides of a continuous side surface and a rear surface of the mobile device 100 (see also FIG. 2). In some embodiments, all four sides of the continuous side surface may be formed of metal and may include polymer or dielectric segments 126 to electrically isolate portions of the continuous side surface. As illustrated in FIG. 1B, the mobile device 100 may include a rear component 103 positioned on top of and/or enclosed by the enclosure 102, as described herein. In some embodiments, a portion of the enclosure 102 may be coupled to internal circuitry of the mobile device 100 and may function as an antenna for sending and receiving wireless signals. As used herein, the rear component 103 may be described as an example of a cover.

A button 116 may protrude from the enclosure 102. The button 116 may be formed for a material, such as a metal, glass, ceramic, and/or plastic, and may be configured to control an operation of the mobile device 100. For example, the button 116 may control a power state, a volume, an application, and so on of the mobile device 100. In some embodiments, the button 116 may be an extruded portion of the enclosure 102. In some embodiments, the button 116 may protrude through a hole formed in the enclosure 102. One or any number of buttons may be provided on or within the mobile device 100.

The enclosure 102 may define one or more holes, openings, or ports that are integrated with electronic components. As shown in FIG. 1A, the enclosure 102 may define a hole including a first microphone assemb1y106, a hole including a first speaker assemb1y108, a hole including a charging port 110, a hole including a second speaker assembly 112, and a hole including a second microphone assembly 114. The charging port 110 may be configured to receive a cable and may be coupled to an external power source (e.g., a wall outlet connected to an electrical system) in order to recharge the mobile device 100 or to otherwise connect the mobile device 100 to a power supply.

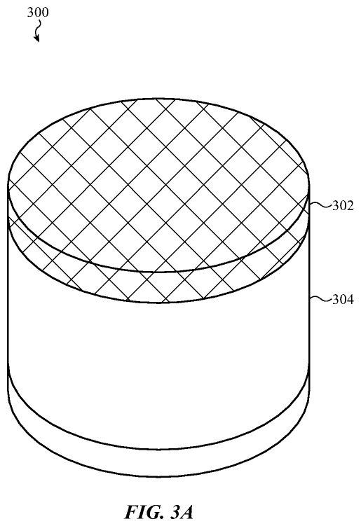

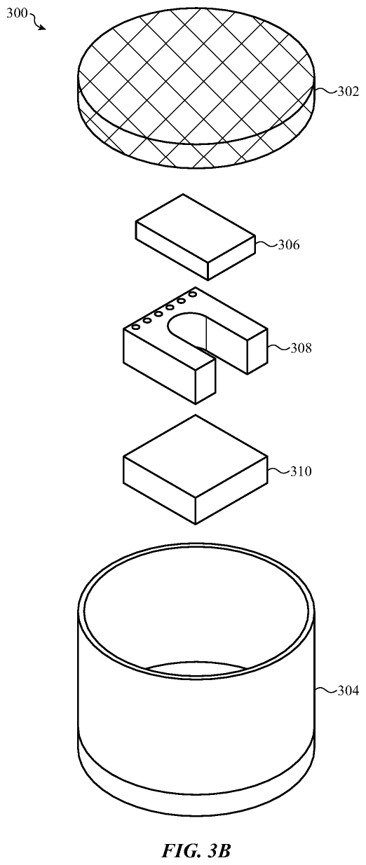

The first microphone assemblyl06 may be positioned at a bottom portion of the mobile device 100 and may receive sound during, for example, a phone call. The first microphone assemblyl06 may be positioned within one or a number of holes that extend through a thickness of the enclosure 102. The holes may comprise any number of openings (e.g., six openings are depicted in FIG. 1A, though any number of openings may be used). As described herein and as depicted in FIGS. 3A & 3B, a microphone assembly may have a height substantially equivalent to a thickness of the enclosure 102 (corresponding to a depth of the hole that extends through the enclosure 102). In some embodiments, a top surface of the microphone assembly 106 positioned within one or a number of holes may be flush with the surrounding portion of the enclosure 102. In some embodiments, a top surface of a microphone assembly 106 may below or above a surface of the enclosure 102.

The first speaker assembly 108 may be positioned on the other side of the charging port 110 with respect to the first microphone assembly 106 and may be configured to emit sound corresponding to a vibration of components of the first speaker assembly 108. The first speaker assembly 108 may be positioned within one or a number of holes formed in the enclosure 102 or may be positioned behind the enclosure 102 to emit sound through the holes. In some embodiments, the location of the first speaker assembly 108 and the first microphone assembly 106 may be switched.

The mobile device 100 may additionally include a second microphone assembly 114 and a second speaker assembly 112. The second microphone assembly 114 and the second speaker assembly 112 may be substantially similar to the first microphone assembly 106 and the first speaker assembly 108, but may be different in shape, electrical component quality, depth, and the like. For example, the second speaker assembly 112 may be larger to better impart sound to a user's ear during a phone call. A hole in which the second speaker assembly 112 is integrated may also be in an oblong shape that may be more suitable for a telephone headset when the mobile device 100 is operated as a mobile phone.

In some embodiments, the assemblies 106, 108, 112, and 114 maybe positioned at a different location with respect to the enclosure 102

FIG. 1B illustrates an isometric view of a back portion of the mobile device 100 depicted in FIG. 1A. In the view depicted in FIG. 1B, a set of buttons 118, a rear component 103 of the enclosure 102, a protruding portion 120, a number of camera assemblies 122, and a rear-facing microphone assembly 124.

The set of buttons118 may operate as a volume control. For example, one button of the set of buttons 118 may increase a volume of the mobile device 100 and another button of the set of buttons 118 may decrease a volume of the mobile device 100. The set of buttons 118 may additionally or alternatively be capable of controlling other operations of the mobile device 100. The set of buttons 118 may extend through a hole in the enclosure 102 or may extend from the enclosure 102 itself.

The rear component 103 may be a continuation of the enclosure 102 or may include an element positioned on top of, coupled to, and/or within the enclosure 102. In some embodiments, the rear component 103 may be a transparent and/or light transmissive component defining the rear surface of the mobile device 100. If the rear component 103 is formed from a glass, the glass may include frosted or polished glass. The frosted glass may appear opaque and may increase frictional forces between a user's hand and the mobile device 100. Polished glass may also be present, either partially or entirely, for aesthetic or manufacturing purposes and may decrease frictional forces between the user's hand and the mobile device 100. In some embodiments, the rear component 103 may be formed entirely or partially of glass, metal, ceramic plastic, or other materials suitable for use in the mobile device 100.

The rear component 103 may further include a protruding portion 120. The protruding portion 120 may be at least partially surrounded by the rear component 103 as depicted in FIG. 1B. The protruding portion 120 may have a thickness greater than the surrounding rear component 103. For example, the protruding portion 120 may be at least 10%, 25%, or 50% and up to about 250% thicker than the surrounding rear component 103. In some cases, the protruding portion 120 may have a thickness greater than about 1 mm and less than or equal to about 2 mm and the rear component 102 may have a thickness greater than about 0.5 mm and less than about 1mm. In some embodiments, a ratio between a first thickness of the protruding portion and a second thickness of the base portion is from about 1.5 to about 2.5.

The amount of extension or offset between the protruding portion 120 and the rear component 103 may be from about 0.5 mm to about 1.5 mm. The size of the protruding portion 120 may depend at least in part on the size of a camera assembly and a microphone assembly. In some embodiments, a lateral dimension (e.g., a width) of the protruding portion may be from about 5 mm to about 30 mm or from about 10 mm to about 20 mm.

In some embodiments, the protruding portion 120 may be formed from the same material as the surrounding rear component 103. For example, if the rear component 103 is a glass component, the protruding portion 120 may be glass protruding portion. The type of glass comprising the glass protruding portion 120 may be frosted, clear, or any combination thereof. In another example, if the rear component 103 is a metal or ceramic component, the protruding portion 120 may be a metal or ceramic protruding portion. Any other material, in addition to glass, ceramic, and metal, may be used including plastic, wood, and the like.

In alternative embodiments, the protruding portion 120 may be formed of a material different from the material comprising the rear component 103. For example, if the rear component 103 is a plastic, the protruding portion 120 may be formed from a glass, metal, and/or ceramic. The protruding portion 120 may be integrally formed with the rear component 103 or may be affixed to the rear component 103 by an adhesive or other coupling mechanism. The above examples are merely explanatory and any combination of elements may be used

The protruding portion 120 may include a number of holes, including a number of holes integrated with a number of camera assemblies 122 and a hole integrated with a rear-facing microphone assembly 124. The example of FIG. 1B illustrates three camera assemblies, but, more generally, there may be any number of camera assemblies, such as one, two, three, four, or five camera assemblies. Each one of the camera assemblies 122 may be partially or entirely positioned within a hole extending through the protruding portion 120. In some embodiments, each camera assembly 122 may be identical. In some embodiments, each camera assemb1y122 may include different components and/or lenses and may be configured to capture pictures and/or videos with different focal lengths, clarity, depth of field, color, and the like. In some embodiments, an optical flash element and/or an optical sensor may be provided within an additional hole extending through the protruding portion 120.

Each of the camera assemblies 122 may protrude from, be substantially flush with, or be recessed with respect to the protruding portion 120. In some cases, a camera assembly 122 includes an optical sensing array and/or an optical component such as a lens, filter, or window. In additional cases, a camera assembly 122 includes an optical sensing array, an optical component, and a camera assembly housing surrounding the optical sensing array and the optical components. The camera assembly 122 may also include a focusing assembly. For example, a focusing assembly may include an actuator for moving a lens of the camera assembly 122. In some cases, the optical sensing array may be a complementary metal-oxide semiconductor (CMOS) array or the like. In some embodiments, the holes integrated with the camera assemblies 122 may extend entirely through a thickness of the protruding portion or may extend partially through the thickness of the protruding portion. As examples, the holes and/or camera assemblies 122 may have a lateral dimension (e.g., a width or diameter) from about 1 mm to about 10 mm.

The rear-facing microphone assembly 124 may be positioned proximate to the number of camera assemblies 122 and may be integrated with a hole that extends entirely or partially through a thickness of the protruding portion. In the example depicted in FIG. 1B, the rear-facing microphone assembly 124 has a smaller circumference than the surrounding camera assemblies 122, though in other examples the rear-facing microphone opening 124 may have an identical or larger circumference. In an example, a lateral dimension (e.g., a width or diameter) of the rear-facing microphone assembly and/or associated holes may be less than 0.5 mm.

As discussed herein, a microphone assembly 124 may be positioned within a hole that extends through the protruding portion 120. The microphone assembly 124 may have a surface that is substantially flush, recessed, or protruding with respect to the surface of the protruding portion 120 when installed within the associated hole. In some embodiments, a height of the microphone assembly 124 (see, e.g., FIGS. 3A & 3B) may be substantially equivalent to a thickness of the protruding portion 120.

In some cases, the shape of the rear member 103 may generally correspond to the shape of the front face of the mobile device (see FIG. 1A) and may extend across a substantial entirely of the rear surface of the mobile device 100. In additional cases, the rear member 103 may include multiple transparent and/or light transmissive members. For example, a first transparent and/or light transmissive member may define the first portion of the rear member 103 and a second transparent and/or light transmissive member may define the second portion of the rear member 103. The first transparent and/or light transmissive member and the second transparent and/or light transmissive member may be coupled together by a fastener or other attachment part alone or in combination with an adhesive. The fastener or other attachment part may at least partially define a third region of the rear member 103. The rear member 103 may further include a smudge-resistant coating, a cosmetic coating, or a combination thereof.

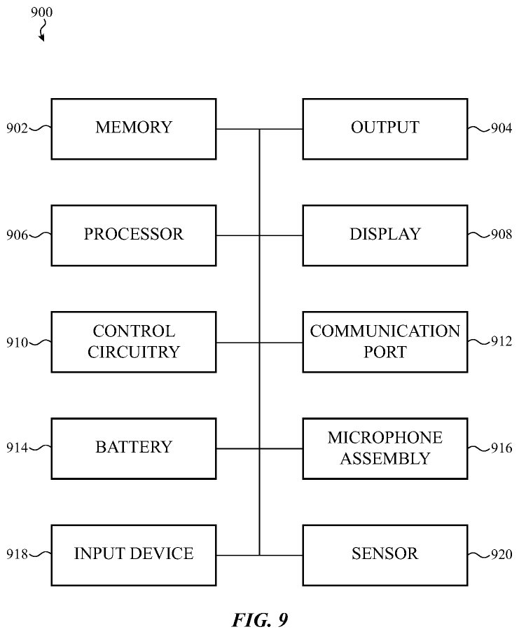

In addition to a display, camera assemblies, and microphone assemblies, the mobile device 100 may include additional components. These additional components may comprise one or more of a processing unit, control circuitry, memory, an input/output device, a power source (e.g., battery), a charging assembly (e.g., a wireless charging assembly), a network communication interface, an accessory, and a sensor. Components of a sample mobile device are discussed in more detail below with respect to FIG. 9. and the description provided with respect to FIG. 9 is generally applicable herein.

FIG. 2 illustrates a partial cross-section of a mobile device 200. The mobile device 200 may be similar to the mobile device 100 of FIGS. 1A and 1B and the cross-section may be taken along A-A. The mobile device 200 may include a front cover assembly 230 at a front (e.g., display-facing) portion of the mobile device 200 and may include a rear cover assembly 236 at a rear (e.g., opposite the display-facing) portion of the mobile device 200. Each of the front cover assembly 230 and the rear cover assembly 236 may be coupled to an enclosure component 256 by a bonding mechanism 258. The bonding mechanism 258 may be an adhesive, a fastener, a weld, a snap-fit, a force-fit, any combination thereof, and the like. The enclosure component 256 may be similar to the enclosure 102 as depicted in FIGs. lA and 1B. The enclosure component 256 at least partially defines an internal cavity 232 of the mobile device 200.

In FIG. 2, relative and/or absolute sizes may be exaggerated to better illustrate certain components of the mobile device 200. For example, the microphone assembly 242 may have a diameter much smaller than it appears in FIG. 2, with respect to the camera assembly 244. Other components and/or layers may be larger, smaller, thinner, or thicker than they appear.

The front cover assembly 230 may include a front glass cover component 250 and the rear cover assembly 236 may include a rear glass cover component 246. The glass cover components 250 and 246 may be formed from a glass, transparent, and/or light transmissive material. In some embodiments, the cover components 250 and 246 may be formed of a metal, plastic, ceramic, and so on. The rear cover assembly 236 may define a protruding portion 240 with protrudes with respect to a base portion 238 due to the greater thickness of the rear glass cover component 246 in the protruding portion 240 area. At least part of the base portion 238 may be substantially adjacent to the protruding portion 240. A hole 243 and a hole 245 may extend through the protruding portion 240. As depicted in FIG. 2, the hole 243 may contain the microphone assembly 242 and the hole 245 may contain the camera assembly 244. In some embodiments, the holes 243 and 245 may extend from a front surface as defined by the protruding portion 240 to a rear surface as defined by the rear glass cover component 246 (e.g., the surface of the rear glass cover component 246 in contact with the cosmetic or decorative coating 248).

In the example shown in FIG. 2, the protruding portion 240 is integrally formed (e.g., as a single piece) with the base portion 238. In some embodiments, the protruding portion 240 may be coupled to the base portion 238 by an adhesive, fastener, and the like. The protruding portion 240 may be formed as a plateau from the base portion 238 and may include slopes and rounded corners. In some embodiments, the protruding portion 240 may be configured with sharp corners and 90-degree edges. The protruding portion 240 is not limited to any particular shape and any type of protrusion may be used. The protruding portion 240 may additionally include textured regions that may have a rougher or smoother texture than the base portion 238 and/or surrounding regions.

The mobile device 200 may further include a display 254 and a touch sensor 252 provided below and coupled to the front glass cover component 250. The display 254 may be any kind of display including a liquid-crystal display (LCD), a light-emitting diode (LED) display, an LED-backlit LCD display, an organic light-emitting diode (OLED) display, and the like. The touch sensor 252 may be configured to detect or measure a location of a touch along the exterior surface of the front glass cover component 250. In some embodiments, the touch sensor 252 may be configured to detect biometric information such as a fingerprint.

The rear cover assembly 236 may include a cosmetic or decorative coating 248 disposed along an interior surface of the rear glass cover component 246. The cosmetic or decorative component may affect the appearance of the rear cover assembly and may function as a masking layer, a color layer, and/or a textured-appearance layer. In the example illustrated in FIG. 2, the cosmetic or decorative coating 248 extends underneath the protruding portion 240 to impart the same cosmetic appearance as is provided to the base portion 238. However, in some embodiments the cosmetic or decorative coating 248 may not extend underneath the protruding portion 240 so as to give the protruding portion 240 a distinct appearance. In some embodiments, a distinct decorative coating may be provided underneath the protruding portion 240 so as to give the protruding portion 240 a distinct appearance (e.g., a different color).

As depicted in FIG. 2, the protruding portion 240 may include a sensing array 234. The sensing array 234 may extend through multiple holes extending through the protruding portion 240 and may comprise a camera assembly 244 positioned within a hole 245 and a microphone assembly 242 positioned within a hole 243. The camera assembly 244 may be coupled to a surface of the rear cover assembly 236 by an adhesive, force fit, or other coupling arrangement. The microphone assembly 242 may additionally be coupled to the rear cover assembly 236 by similar, identical, or distinct mechanisms.

A support structure 260 may be provided underneath the cosmetic or decorative coating 248 and may be coupled to the sensing array 234 to limit bending of the rear cover assembly 236 and, more particularly, the protruding portion 240. Limiting the bending of the rear cover assembly 236 may limit bending-induced tensile stresses that may be applied to the mobile device 200 during a user's operation. Additionally or alternatively, the support structure 260 may provide the shape of the protruding portion 240 by, for example, putting a pressure on the protruding portion 240. The support structure 260 may be sufficiently rigid to provide support while still being partially flexible to avoid cracking or shattering under high stresses.

In some embodiments, the support structure 260 may be a machined chassis or plate and may be formed partially or entirely from a metal, ceramic, glass, plastic, and the like. In some embodiments, the support structure 260 may be used as a camera chassis or housing and may define an internal volume where lens, electronics, optical components, and the like are disposed. The support structure 260 may also include one or more sheet components that help to retain and align the various elements of the sensing array 234 including the camera assembly 244 and one or more other sensors.

A printed circuit board 262 may be provided underneath and/or mounted to the support structure 260. The printed circuit board 262 may be operatively coupled with a battery and/or an external power source and may be configured to provide power to the sensing array 234 and other electronic components of the mobile device 200. In some embodiments, the printed circuit board may convert power of a certain voltage and/or frequency to another voltage and/or frequency to avoid overloading the electrical components. The camera assembly 244 may extend from the surface of the protruding portion 240 to the printed circuit board 262 so that power and/or control is provided to the camera assembly 244.

The microphone assembly 242 may include a flex connector 247 and may be operatively coupled to the printed circuit board 262 by the flex connector 247. The flex connector 247 may be made from a flexible plastic, rubber, metal, any combination thereof, and the like and may be bent to bend around other internal components of the mobile device 200. The flex connector 247 may be positioned below the microphone assembly 242. In this way, the microphone assembly 242 may be operatively coupled to other components of the mobile device 200 by the flex connector. In some embodiments, a rigid microphone connector may be provided instead of the flex connector to provide increased structural rigidity. In some embodiments, both the microphone connector and the flex connector 247 may be provided.

In the example illustrated in FIG. 2, the microphone assembly 242 is substantially flush with a top surface of the protruding portion 240 and components of the microphone assembly 242 are disposed within a hole between a top surface of the protruding portion 240 and a bottom surface of the rear glass cover component 246. In this way, empty space within the hole may be reduced and space within the interior cavity 232 may be increased. In some embodiments, the top surface of the microphone assembly 242 may extend beyond or be recessed with respect to the top surface of the protruding portion 240. Similarly, the bottom surface of the microphone assembly 242 may extend beyond the inner surface of the rear glass cover component 246 or may be recessed with respect to the inner surface of the rear glass cover component 246.

In the example illustrated in FIG. 2, the top surface of the camera assembly 244 extends beyond the top surface of the protruding portion 240. In other embodiments, the top surface of the camera assembly 244 may be flush with or below the top surface of the protruding portion 240. In some cases, a clear or opaque window may be provided over a top surface of the microphone assembly 242a and/or the camera assembly 244 to protect components thereof. In some embodiments, the protruding portion 240 may be removed such that the rear cover assembly 236 is substantially flat across the entire surface.

FIG. 3A illustrates an isometric view of a microphone assembly 300. The microphone assembly 300 may be equivalent to the microphone assembly 242 as depicted in FIG. 2 and/or may be configured to fit in holes 106 and/or 114 as illustrated in FIGS. 1A and 1B.

The microphone assembly 300 may include a wire mesh 302 and a microphone enclosure 304. The wire mesh 302 may operate as a cosmetic mesh and may prevent an ingress of particles, such as smoke, dust, and/or water, from reaching an internal area of the microphone assembly 300. The wire mesh 302 may be formed of a grid of metallic wire or strips or may be formed of another material such as plastic, ceramic, or glass. In some embodiments, the wire mesh 302 may include a cosmetic coating such as a paint, film, physical vapor deposition, and/or anodized portion to display a particular color or combination of colors (e.g., black or white). The cosmetic coating may also reduce chemical reactions with the environment, such as a rusting reaction. In some embodiments, the wire mesh 302 may have a between 100 and 200 threads per inch weave and may be comprise wire with a between 0.1 mm and 0.025 mm diameter. In some embodiments, the wire mesh 302 may comprise multiple parts bonded together by, for example, an adhesive or a weld. For example, a reinforcing mesh may be bonded to an internal surface of the wire mesh 302.

The microphone enclosure 304 illustrated in FIG. 3A is a cylindrical shape. The microphone enclosure 304 may include depressions at a top and bottom circumferential portion thereof to better couple the wire mesh 302 and/or an electrical connector (e.g., a flex connector). In some embodiments, the microphone enclosure 304 may be a cylinder without any such depressions.

The microphone enclosure 304 may be formed of one piece of material, such as a metal can, or may be formed from a number of components that are bonded together by friction, an adhesive, a weld, and the like. The microphone enclosure may be comprised of any material, or combination of materials, such as a glass, a metal, a plastic, and the like.

In some embodiments, the microphone enclosure 304 may include structural extensions to engage with walls of a hole when installed into a mobile device. In some embodiments, the microphone enclosure 304 and/or the wire mesh 302 may have different shapes, such as a rectangular prism, instead of a cylinder.

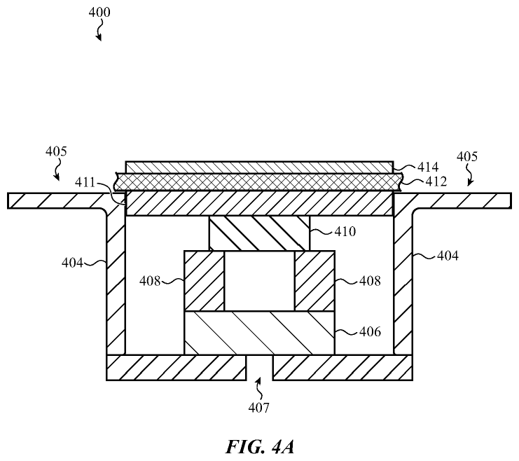

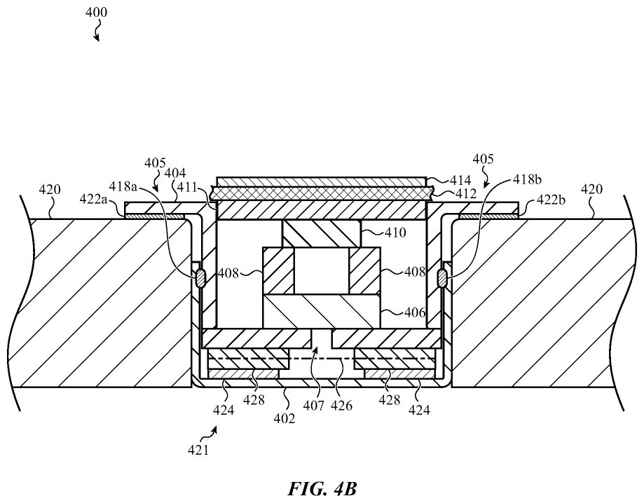

FIG. 3B illustrates an exploded view of the microphone assembly 300 depicted in FIG. 3A. As shown in FIG. 3B, the microphone assembly 300 is substantially hollow to hold internal microphone components. A substrate may be placed at an end of the microphone enclosure 304 opposite from the wire mesh 302 (see, e.g., FIG. 4A).

The wire mesh 302 may be a wire cap with wire extensions around a circumference of the wire cap. In some embodiments, the wire extensions may be welded or otherwise coupled to the microphone enclosure 304.

The microphone assembly 300 may further include an integrated circuit 310 (e.g., a controller), an interposer 308, and a MEMS microphone device 306, which may be stacked as shown. The MEMS microphone device 306 may include a flexible diaphragm which may vibrate in response to received sound. The flexible diaphragm may be coupled to electrical components which may convert the vibrations into electrical signals. The electrical signals may then be used as part of an audio data or audio recording and may be used to produce sound via, for example, a speaker. The MEMS microphone device 306 may additionally include a hole in a portion thereof. The hole may be proximate to the wire mesh 302 and may receive sound information from an external environment surrounding the microphone assembly 300.

In some embodiments, the microphone assembly 300 may be sealed to prevent air from reaching internal components. In such an embodiment, air may still transmit sound vibrations to a hole in the MEMS microphone device 306, but may be prevented from entering any other location of the microphone assembly 300.

The integrated circuit 310 may be electrically coupled to the MEMS microphone device 306 via the interposer 308. The integrated circuit 310 may include circuitry for amplifying an electronic signal, may filter out signals from the MEMS microphone device 306, and may perform other control-related functions. As discussed herein, the integrated circuit 310 may be an application specific integrated circuit (ASIC) that includes signal processing circuitry including analog to digital conversion and other signal processing hardware and/or firmware. The integrated circuit 310 may also include a microprocessor and other circuitry used to process signals received by the MEMS microphone device 306.

The interposer 308 may be positioned between the MEMS microphone device 306 and the integrated circuit 310 and may operatively couple the two components. As depicted in FIG. 3B, the interposer 308 may comprise a number of conductive columns which may be formed of conductive material. The conductive wires may contact conductive portions of the integrated circuit 310 and the MEMS microphone device 306. In the example depicted, the interposer 308 may form an arch-shape in order to provide a secure contact while also allowing a diaphragm of the MEMS microphone device 306 to vibrate in response to sound. In some embodiments, the interposer 308 may be a conductive wire and/or may include different shapes, as discussed herein. The interposer 308 may be formed of one or a combination of materials including dielectric materials, polymers, phenolic, composites, any combination thereof, and the like. The conductive columns of the interposer 308 may be formed from a conductive material such as a metal and/or conductive alloy.

In some embodiments, additional components may be provided as part of the microphone assembly 300, including adhesives, support structures, filters, substrate layers, and the like. A diameter of the microphone assembly 300 may be between 1 mm and 5 mm, in some embodiments, or may be greater than 5 mm. A height of the microphone assembly 300 may be between 0.5 mm and 3 mm, in some embodiments, or may be greater than 3 mm. In one example, the height of the microphone assembly 300 may be 1.5 mm and the diameter of the microphone assembly 300 may be 2.5 mm.

FIG. 4A illustrates a partial cross-section of a portion of a microphone assembly 400. The microphone assembly 400 may include a microphone enclosure 404 which may be a cylindrical shape with a flange 405. The flange 405 may be formed as a single piece with the microphone enclosure 404 or may be affixed to the microphone enclosure 404 by an adhesive, a fastener, an engagement feature, and the like. In some embodiments, the microphone enclosure 404 may be formed of a single piece (e.g., a hollow metallic cylinder). In some embodiments, the microphone enclosure 404 may be formed of a number of different parts. For example, a top portion of the microphone enclosure 404 may act as a lid and may be inserted during an installation process. In some embodiments, the microphone enclosure 404 may be made of a ceramic, metal, glass, or plastic and may be formed by machining, die case, molding, stamping, or deep drawing techniques.

A substrate layer 411 may be provided on top of an integrated circuit 410 and may operatively couple the integrated circuit 410 with a flex connector 412. The substrate layer 411 may seal the microphone enclosure 404 and may operate as a lid. In some embodiments, the substrate layer 411 may be a printed circuit board and may include one or a number of electrical traces.

In some embodiments, the substrate layer 411 may be bonded with the flex connector 412 with a laminate and may operatively couple the integrated circuit 410 with the flex connector 412. In some embodiments, the integrated circuit 410 may be directly coupled with the flex connector 412. As depicted in FIG. 4A, the microphone enclosure 404 may define an acoustic port 407 at a partial contact point with a MEMS microphone device 406. As described above, this acoustic port 407 may receive sound waves and may permit these sound waves to come into contact with the MEMS microphone device 406. The flex connector 412 may be operatively coupled with additional electronic components (e.g., a motherboard and/or a printed circuit board) and may electrically couple various components to one another.

In some embodiments, the flex connector 412 may be a flexible circuit having a flexible dielectric substrate with an array of electrically conductive traces that are configured to transmit signals from the ASIC to other circuitry in the device.

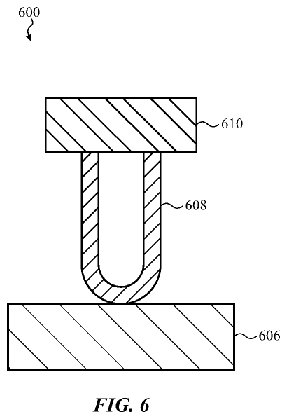

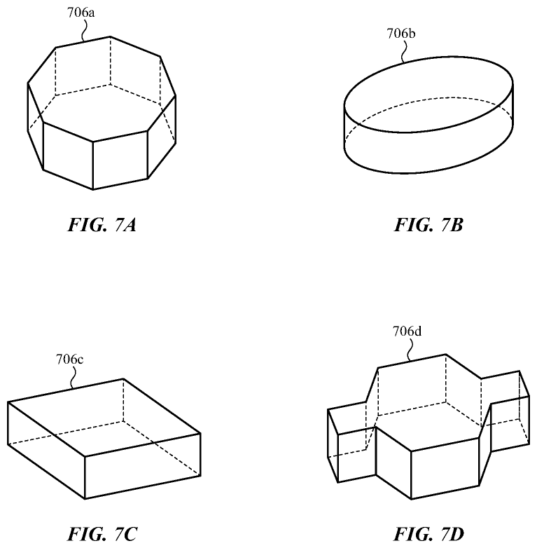

As the microphone enclosure 404 may be hollow, a stack-up including a MEMS microphone device 406, an interposer 408, and an integrated circuit 410 may be disposed in an internal cavity of the microphone enclosure 404. The MEMS microphone device 406 may be a rectangular cuboid and may have a surface proximate to the acoustic port 407. An interposer 408 may be structurally and electrically coupled with the MEMS microphone device 406 opposite from the surface proximate to the acoustic port 407. The shape of the interposer 408 may be similar to the shape depicted in FIG. 3B (e.g., with a u-shaped profile), may have a shape as shown in FIGS. 6 and 7A-7D, or may have any shape which allows a rear surface of the MEMS microphone device 406 to vibrate in response to sound waves. The rear surface of the MEMS microphone device 406 may be a flexible diaphragm or may otherwise require an open area in order to provide for optimal operation of the MEMS microphone device.

The integrated circuit 410 may comprise one or a number of circuits and may include an amplifier, an analog-to-digital converter, a pulse-density modulator, a pulse-width modulator, a power management circuit, a clock, a controller, a serial port, and the like. The integrated circuit 410 may provide audio filtering to isolate certain frequencies (e.g., speech frequencies) while filtering out or muting frequency ranges above or below a certain range. The integrated circuit 410 may amplify a signal generated by the MEMS microphone device 406 and may convert the received signal into a digital signal. The digital signal may be filtered and/or may be modulated into a particular format as expected by various electrical components and/or software components of a mobile device. The digital signal (either a modulated or unmodulated digital signal) may contain sound information that was received by the MEMS microphone device 406 and may store the sound information in an internal or external storage, may direct an associated speaker to emit the sound, and/or may transmit the audio data to another device (e.g., as in a phone call). As depicted in FIG. 4A, the integrated circuit 410 may be a rectangular cuboid. In some embodiments, the integrated circuit 410 may have any of a number of shapes, including a cylinder.

Each of the components of the microphone stack may include conductive elements and/or conductive terminals may be electrically coupled or connected in order to operably couple the components together. For example, the interposer may have conductive columns that electrically couple the integrated circuit 410 to the MEMS microphone device 406. The integrated circuit 410 may additionally be electrically coupled with a substrate layer 411 and/or a flex connector 412, which may couple the integrated circuit 410 with other electronic components of a mobile device. A stiffener 414 may be provided on a surface of the flex connector 412 to provide structural support to the flex connector 412 and/or to avoid bending, which may damage the flex connector 412. The stiffener may be adhered or otherwise bonded to a surface of the substrate 411 to help prevent peeling or disconnection between the flex connector 412 and the substrate 411.

The flex connector 412 may be operatively coupled to an internal printed circuit board, as depicted in FIG. 2. In this way, each of the components of the microphone stack may be operatively coupled with the internal printed circuit board. FIG. 4B illustrates a microphone assembly 400 when positioned in a hole within a glass component 420 (e.g., the rear cover assembly 236 depicted in FIG. 2). As depicted in FIG. 4B, the flange 405 may be configured to fit over a rear surface of the glass component 420. An attachment 422 may be provided between the flange 405 and the glass component 420 to strengthen a stability of the microphone assembly 400 when installed in the glass component 420. In some embodiments, a cosmetic or decorative coating may be disposed between the attachment 422 and the glass component 420, as depicted in FIG. 2. A hole 421 may be formed in the glass component 420 and may include the microphone assembly 400.

A wire mesh 402 may be bonded to the microphone enclosure 404 by an attachment 418. As illustrated in FIG. 3A, the wire mesh 402 may be circularly shaped with perpendicularly protruding edges. The attachment 418 may be similarly disposed around an internal circumference of the wire mesh 402 or may be placed at limited positions around the internal circumference. In some embodiments, the attachment 418 may be an adhesive, a weld, an o-ring, tape, a mechanical coupling mechanism, or any other coupling mechanism. In some embodiments, the attachment 418 may act as a waterproofing mechanism and may prevent water or debris from entering the gap between the microphone enclosure 404 and the wire mesh 402. In FIG. 4B, the wire mesh 402 is in contact with the glass component 420. In some embodiments, the wire mesh 402 may be separated from the glass component 420 so that a gap between the wire mesh 402 and the glass component 420 exists. The wire mesh 402 may be flush with an external surface of the glass component 420 or may be positioned above or below the external surface of the glass component 420. In some embodiments, the glass component 420 may include chamfered edges proximate to the microphone enclosure 404 and the top surface of the wire mesh 402 may be positioned between 0.1 mm and 0.3 mm below the external surface of the glass component 420.

A stiffener 424, an adhesive layer 428, and an acoustic mesh 426 may be provided between an internal surface of the wire mesh 402 and an external surface of the microphone enclosure 404. The stiffener 424 may be coupled with the wire mesh 402 in order to prevent forces, stresses, or strains from deforming the wire mesh 402. The adhesive layer 428 may also be coupled to the stiffener 424 to couple the stiffener 424 with the acoustic mesh 426. The stiffener 424 may be formed of a stiff polymer, a metal, a plastic, or any other material with sufficient stiffness.

The acoustic mesh 426 may be an acoustically transparent mesh (e.g., a mesh that permits sound to propagate through) while preventing debris, dust, and/or moisture from coming into contact with the electronic components of the microphone assembly 400 (e.g., the MEMS microphone device 406). The acoustic mesh 426 may be formed of a mesh (e.g., a polyethylene terephthalate, PET, fabric, polyurethane, expanded polytetrafluoroethylene), a woven polymer, and the like. In some embodiments, the acoustic mesh 426 may be configured to absorb or dampen sound so as to reduce undesired noise from being detected by the microphone assembly 400. In this way, the acoustic mesh 426 may assist in a filtering and/or waterproofing operation. In some embodiments, the acoustic mesh 426 may positioned between the adhesive layer 428 (e.g., the adhesive layer 428 may be two adhesive layers positioned along both sides of the acoustic mesh 426).

An adhesive layer 428 may be positioned at each side of an end portion of the acoustic mesh 426 and may bond the acoustic mesh 426 to the microphone enclosure 404 and the stiffener 424. In some embodiments, the adhesive layer 428 may be between 0.05 mm and 0.20 mm thick and may consist of an acrylic adhesive on both sides of a polyester carrier.

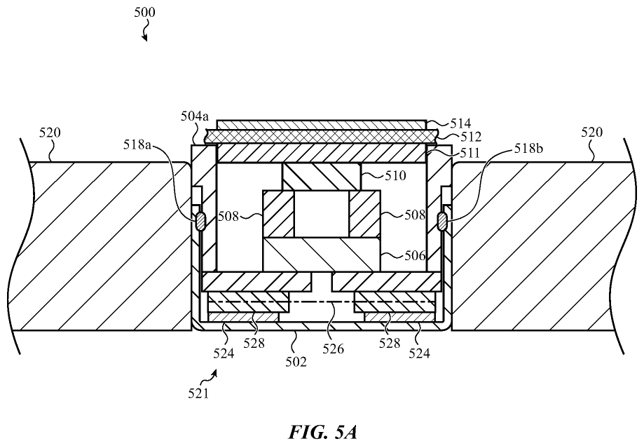

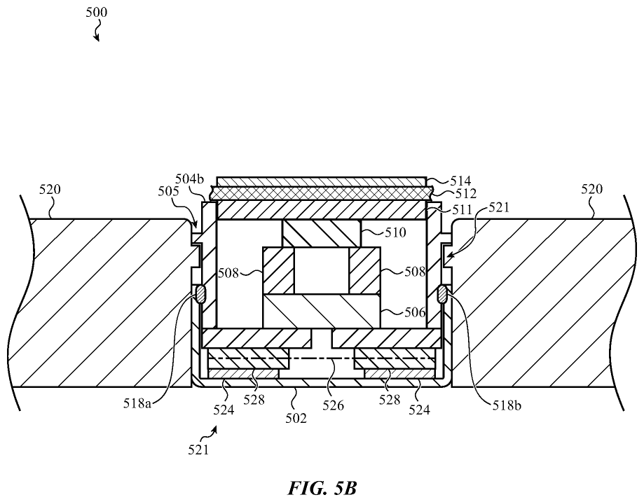

FIGS. 5A and 5B illustrate alternate embodiments of a microphone assembly inserted into a hole as defined by a surrounding glass component. FIG. 5A illustrates an example of a microphone assembly 500a with a microphone enclosure 504a that expands in a radial direction after a wire mesh portion 502 ends. In this way, a top portion of the microphone enclosure 504a abuts a glass component 520a and is force fit against the glass component 520a. The frictional forces between the microphone enclosure 504a may securely position the microphone enclosure 504a within the hole in the glass component 520a without risk of falling out. In some embodiments, an adhesive or other securement method may be provided between the microphone enclosure 504a and the glass component 520a. A hole 521 may be formed in the glass component 520a or 520b and may include the microphone assembly 500.

In FIGS. 5A and 5B, reference numbers similar to those presented in FIGS. 4A and 4B reference similar features, except where otherwise mentioned.

A flex connector 512 may be operatively coupled with a substrate layer 511 in order to operatively couple an internal circuit board to the microphone stack-up including the integrated circuit 510, the interposer 508, and the MEMS microphone device 506.

A stiffener 514 may be provided on a surface of the flex connector 512 to provide structure to the flex connector 512 and/or to avoid bending along certain portions of the flex connector 512, which may damage the flex connector 512.

In the example depicted in FIG. 5A, the wire mesh 502 is substantially flush with the surrounding surface of the glass component 520a. In other examples, the wire mesh 502 may be sunken or extruded below or above, respectively, the glass component 520a.

FIG. 5B illustrates an embodiment where a microphone enclosure 504b is installed in a snap fit arrangement with a surrounding glass component 520b. The microphone enclosure 504b may include protrusions 505. The microphone enclosure 504b and the protrusions 505 may deform when inserted into a hole defined by a glass component 520b. The glass component 520b may include protrusions 521, which are substantially rigid. As the protrusions 505 of the microphone enclosure 504b come into a sliding contact with the protrusions 521 of the glass component 520b, a circumference of the microphone enclosure 504b may reduce (e.g., the microphone enclosure 504b may deform). As the microphone enclosure 504b slides past the protrusions 521 of the glass component 520b, the microphone enclosure 504b may return to the original circumference.

In some embodiments, the protrusions 505 and/or the protrusions 521 may include sloped portions along a direction of installation so that a deformation of the microphone enclosure 504b may more easily occur. In some embodiments, additional protrusions from the glass component may be formed along a rear side of the protrusions 505 of the microphone enclosure 520a. In this way, the protrusions 505 of the microphone enclosure 504b may be surrounded by protrusions of the glass component 520b.

The protrusions described herein may extend along the entirety of an internal circumference (with respect to the glass component 520b) and/or the entirety of an external circumference (with respect to the microphone enclosure 504b). In some embodiments, the respective protrusions may be bumps along only a portion of the respective circumferences. The protrusions may either be integrated with the respective glass component 520b and the microphone enclosure 504b or may be a discrete object affixed to the glass component 520b or microphone enclosure 504b by an adhesive, weld, or other bonding mechanism.

FIG. 6 illustrates an alternate embodiment of a microphone stack-up 600. The microphone stack-up may include a MEMS microphone device 606, an integrated circuit 610, and a wire interposer 608. The wire interposer 608 may be formed entirely or partially of a conductive wire and may operatively couple the MEMS microphone device 606 and the integrated circuit 610. In some embodiments, the wire interposer 608 may include a plastic, rubber, paint, or other covering to insulate a portion of the wire interposer 608 that is not in contact with either the MEMS microphone device 606 or the integrated circuit 610. The wire interposer 608 may be affixed (e.g., welded or soldered) to the integrated circuit 610, the MEMS microphone device 606, or both.

FIGS. 7A-7D illustrate multiple examples of a MEMS microphone device. A surface area of the MEMS microphone device may be maximized as received sound resolution may increase as the surface area of the MEMS microphone device increases.

As illustrated in FIG. 7A, the example MEMS microphone device 706a may have an octagonal shape. For the MEMS microphone device 706a, an associated diaphragm may share a substantially similar shape or may define another shape (e.g., a circle) that stretches across the MEMS microphone device 706a.

As illustrated in FIG. 7B, a MEMS microphone device 706b may define an oval shape. As illustrated in FIG. 7C, a MEMS microphone device 706c may define a rhombus shape. As illustrated in FIG. 7D, a MEMS microphone device 706d may define an irregular polygon shape. Each of these MEMS microphone device shapes may be incorporated into any of the microphone stack-ups as depicted in FIGS. 1-6.

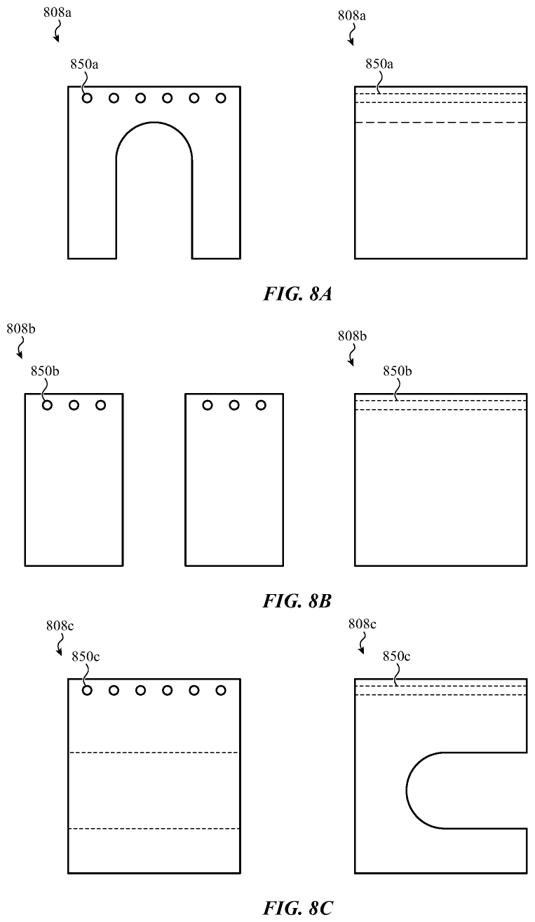

FIGS. 8A-8C illustrate a number of different forms for an interposer as depicted and described above.

As illustrated in FIG. 8A, a u-shaped interposer 808a may include a number of conductive columns 850a. In the left-most figure in FIG. 8A, the u-shaped interposer 808a is depicted in a top-down view and the conductive columns 850a extend through a thickness of the u-shaped interposer 808a. In the right-most figure in FIG. 8A, the u-shaped interposer 808a is depicted in a side view. The u-shaped interposer 808a may be substantially similar to the interposer 308 depicted in FIG. 3A and may be disposed between a MEMS microphone device and an integrated circuit. While described as a “u-shaped interposer” any interposer that is configured to at least partially surround a central portion of the MEMS microphone device, such as discussed with reference to FIGS. 8A and 8B, may be used.

As illustrated in FIG. 8B, an interposer 808b may include two discrete segments which are not directly connected. In this embodiment, conductive columns 850b may extend through a portion of each section of the interposer 808b. The two pieces of the interposer 808b may be disposed between a MEMS microphone device and an integrated circuit, as discussed herein. The left-most figure in FIG. 8B may be a top-down view of the interposer 808b and the right-most figure in FIG. 8B may be a side view of the interposer 808b.

As illustrated in FIG. 8C, an interposer 808c may be formed as a rectangular prism with an arch portion. From a top view, the interposer 806c may appear as a square or a rectangular with a number of conductive columns 850c. In this way, an integrated circuit placed on top of the interposer 808c may contact a large portion of the interposer 808c. The left-most figure in FIG. 8C may be a top-down view of the interposer 808c and the right-most figure in FIG. 8C may be a side view of the interposer 808c.

As described above, a MEMS microphone device may require empty space proximate to the MEMS microphone device in order for a diaphragm thereof to have space to freely vibrate. A side view of the interposer 808c depicts an arch which may permit a diaphragm of a MEMS microphone device to freely vibrate. In a microphone stack-up including the interposer 808c, an integrated circuit may be positioned on the depicted top surface and a MEMS microphone device may be positioned below the depicted bottom surface. Conductive columns 850c may extend through a thickness of the interposer 808c.

FIG. 9 shows a block diagram of a sample mobile device that can incorporate a microphone assembly within a hole in a glass component. The schematic representation depicted in FIG. 9 may correspond to components of the devices depicted in FIGS. 1-8 as described above. However, FIG. 9 may also more generally represent other types of electronic devices with cover assemblies as described herein.

In embodiments, an mobile device 900 may include sensors 920 to provide information regarding configuration and/or orientation of the mobile device in order to control the output of the display. For example, a portion of the display 908 may be turned off, disabled, or put in a low energy state when all or part of the viewable area of the display 908 is blocked or substantially obscured. As another example, the display 908 may be adapted to rotate the display of graphical output based on changes in orientation of the device 900 (e.g., 90 degrees or 180 degrees) in response to the device 900 being rotated.

The mobile device 900 also includes a processor 906 operably connected with a computer-readable memory 902. The processor 906 may be operatively connected to the memory 902 component via an electronic bus or bridge. The processor 906 may be implemented as one or more computer processors or microcontrollers configured to perform operations in response to computer-readable instructions. The processor 906 may include a central processing unit (CPU) of the device 900. Additionally, and/or alternatively, the processor 906 may include other electronic circuitry within the device 900 including application specific integrated chips (ASIC) and other microcontroller devices. The processor 906 may be configured to perform functionality described in the examples above.

The memory 902 may include a variety of types of non-transitory computer-readable storage media, including, for example, read access memory (RAM), read-only memory (ROM), erasable programmable memory (e.g., EPROM and EEPROM), or flash memory. The memory 902 is configured to store computer-readable instructions, sensor values, and other persistent software elements.

The mobile device 900 may include control circuitry 910. The control circuitry 910 may be implemented in a single control unit and not necessarily as distinct electrical circuit elements. As used herein, “control unit” will be used synonymously with “control circuitry.” The control circuitry 910 may receive signals from the processor 906 or from other elements of the mobile device 900. The control circuity 910 may partially control and/or receive operations of a microphone assembly as described herein.

As shown in FIG. 9, the mobile device 900 may include a battery 914 that may be configured to provide electrical power to the components of the mobile device 900. The battery 914 may include one or more power storage cells that are linked together to provide an internal supply of electrical power. The battery 914 may be operatively coupled to power management circuitry that is configured to provide appropriate voltage and power levels for individual components or groups of components within the mobile device 900. The battery 914, via power management circuitry, may be configured to receive power from an external source, such as an alternating current power outlet. The battery 914 may store received power so that the mobile device 900 may operate without connection to an external power source for an extended period of time, which may range from several hours to several days.

In some embodiments, the mobile device 900 includes one or more input devices 918. The input device 918 is a device that is configured to receive input from a user or the environment. The input device 918 may include, for example, a push button, a touch-activated button, capacitive touch sensor, a touch screen (e.g., a touch-sensitive display or a force-sensitive display), capacitive touch button, dial, crown, or the like. In some embodiments, the input device 918 may provide a dedicated or primary function, including, for example, a power button, volume buttons, home buttons, scroll wheels, and camera buttons.

The mobile device 900 may also include one or more sensors 920, such as a force sensor, a capacitive sensor, an accelerometer, a barometer, a gyroscope, a proximity sensor, a light sensor, or the like. The sensors 920 may be operably coupled to processing circuitry. In some embodiments, the sensors 920 may detect deformation and/or changes in configuration of the mobile device and be operably coupled to processing circuitry which controls the display based on the sensor signals. In some implementations, output from the sensors 920 is used to reconfigure the display output to correspond to an orientation or folded/unfolded configuration or state of the device. Example sensors 920 for this purpose include accelerometers, gyroscopes, magnetometers, and other similar types of position/orientation sensing devices. In addition, the sensors 920 may include an acoustic sensor, light sensor, optical facial recognition sensor, or other types of sensing device.

In some embodiments, the mobile device 900 includes one or more output devices 904 configured to provide output to a user. The output device 904 may include display 908 that renders visual information generated by the processor 906. The output device 904 may also include one or more speakers to provide audio output. The output device 904 may also include one or more haptic devices that are configured to produce a haptic or tactile output along an exterior surface of the device 900.

The display 908 may include a liquid-crystal display (LCD), a light-emitting diode (LED) display, an LED-backlit LCD display, an organic light-emitting diode (OLED) display, an active layer organic light-emitting diode (AMOLED) display, an organic electroluminescent (EL) display, an electrophoretic ink display, or the like. If the display 908 is a liquid-crystal display or an electrophoretic ink display, the display 908 may also include a backlight component that can be controlled to provide variable levels of display brightness. If the display 908 is an organic light-emitting diode or an organic electroluminescent-type display, the brightness of the display 908 may be controlled by modifying the electrical signals that are provided to display elements. In addition, information regarding configuration and/or orientation of the mobile device may be used to control the output of the display as described with respect to input devices 918. In some cases, the display is integrated with a touch and/or force sensor in order to detect touches and/or forces applied along an exterior surface of the device 900.

The mobile device 900 may also include a communication port 912 that is configured to transmit and/or receive signals or electrical communication from an external or separate device. The communication port 912 may be configured to couple to an external device via a cable, adaptor, or other type of electrical connector. In some embodiments, the communication port 912 may be used to couple the mobile device 900 to a host computer.

The mobile device 900 may also include at least one microphone assembly 916, such as described herein. The microphone assembly 916 may be configured to convert acoustic signals into electrical signals and may record or otherwise capture audio data. In some embodiments, the microphone assembly 916 may be proximate to a camera assembly and may be positioned within a hole on a protrusion of a rear glass component.

As used herein, the terms “about,” “approximately,” “substantially,” “similar,” and the like are used to account for relatively small variations, such as a variation of +/−10%, +/−5%, +/−2%, or +/−1%. In addition, use of the term “about” in reference to the endpoint of a range may signify a variation of +/−10%, +/−5%, +/−2%, or +/−1% of the endpoint value. In addition, disclosure of a range in which at least one endpoint is described as being “about” a specified value includes disclosure of the range in which the endpoint is equal to the specified value.

The following discussion applies to the mobile devices described herein to the extent that these devices may be used to obtain personally identifiable information data. It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not intended to be exhaustive or to limit the embodiments to the precise forms disclosed. It will be apparent to one of ordinary skill in the art that many modifications and variations are possible in view of the above teachings.

What is claimed is:

1. A mobile device comprising:
a touch-sensitive display;
an enclosure at least partially surrounding the touch-sensitive display;
a glass component coupled to the enclosure and defining a hole that extends through the glass component; and
a microphone assembly comprising:
a microphone enclosure positioned within the hole and coupled to the glass component, the microphone enclosure defining an acoustic port;
a micro-electro-mechanical system (MEMS) microphone device positioned within the microphone enclosure and adjacent to the acoustic port;
an integrated circuit positioned within the microphone enclosure; and
an interposer positioned between the MEMS microphone device and the integrated circuit, the interposer operatively coupling the MEMS microphone device and the integrated circuit.

2. The mobile device of claim 1, wherein:
the glass component further defines a protruding portion and a base portion surrounding the protruding portion;
the protruding portion extends outward from the base portion; and
the hole extends through the protruding portion of the glass component.

3. The mobile device of claim 2, wherein:
the protruding portion has a first thickness greater than 1 mm and less than or equal to 2 mm;
the base portion has a second thickness greater than 0.5 mm and less than 1 mm; and
the microphone enclosure has a height that is equal to or less than the first thickness.

4. The mobile device of claim 2, wherein:
the enclosure defines an internal cavity of the mobile device;
a printed circuit board is disposed within the internal cavity; and
at least a portion of the microphone assembly is operatively coupled to the printed circuit board.

5. The mobile device of claim 4, further comprising a support structure coupled to the printed circuit board and configured to limit a bending of the protruding portion.

6. The mobile device of claim 1, wherein:
the glass component defines a rear surface of the mobile device;
the microphone assembly further comprises a wire mesh coupled to the microphone enclosure; and
the wire mesh is flush with the rear surface.

7. The mobile device of claim 6, wherein the microphone assembly further comprises:
a stiffener coupled to the wire mesh; and
an acoustic mesh coupled to the microphone enclosure and the stiffener and configured to inhibit an ingress of particles toward the MEMS microphone device.

8. The mobile device of claim 1, wherein:
the interposer has a u-shaped profile that partially surrounds a center region of the MEMS microphone device; and
the u-shaped profile of the interposer allows at least a portion of a surface of the MEMS microphone device to vibrate in response to acoustic vibrations.

9. A microphone assembly comprising:
a microphone enclosure configured to engage with at least a portion of a cover of a mobile device and defining an acoustic port;
a micro-electro-mechanical system (MEMS) microphone device positioned within the microphone enclosure and adjacent to the acoustic port;
an integrated circuit positioned within the microphone enclosure; and
an interposer positioned between the MEMS microphone device and the integrated circuit, the interposer operatively coupling the MEMS microphone device and the integrated circuit.

10. The microphone assembly of claim 9, wherein:
the interposer at least partially surrounds a portion of a surface of the MEMS microphone device; and
the interposer comprises a set of electrically conductive columns that operatively couple the MEMS microphone device with the integrated circuit.

11. The microphone assembly of claim 9, wherein:
the microphone enclosure comprises:
a first portion having a first circumference; and
a second portion having a second circumference, the second circumference larger than the first circumference; and
the second portion of the microphone enclosure is attached to the cover.

12. The microphone assembly of claim 9, wherein:
the microphone enclosure comprises a flange; and
the flange is attached to the cover.

13. The microphone assembly of claim 9, further comprising a wire mesh coupled to the microphone enclosure.

14. The microphone assembly of claim 13, further comprising:
a stiffener coupled to the wire mesh; and
an acoustic mesh coupled to the microphone enclosure and the stiffener and configured to prevent particles from reaching the MEMS microphone device.

15. A mobile device comprising:
an enclosure defining a side surface of the mobile device;
a rear cover assembly coupled to the enclosure and defining:
a base portion;
a protruding portion extending from the base portion; and
a hole extending through the protruding portion; and
a microphone assembly comprising:
a microphone enclosure positioned within the hole and defining an acoustic port; and
a micro-electro-mechanical system (MEMS) microphone device positioned within the microphone enclosure and configured to receive acoustic signals through the acoustic port.

16. The mobile device of claim 15, wherein:
the microphone assembly further comprises:
an integrated circuit positioned within the microphone enclosure; and
an interposer positioned between the MEMS microphone device and the integrated circuit; and
the interposer operatively couples the MEMS microphone device and the integrated circuit.

17. The mobile device of claim 15, wherein:
the rear cover assembly is a glass rear cover assembly; and
a ratio between a first thickness of the protruding portion and a second thickness of the base portion is from about 1.5 to about 2.5.

18. The mobile device of claim 15, wherein:
the protruding portion defines a front surface;
the rear cover assembly defines a rear surface opposite from the front surface;
the hole extends from the front surface to the rear surface;
a flex connector is positioned over the rear surface of the rear cover assembly and is operatively coupled to the microphone assembly; and
a top surface of the microphone assembly is flush with the front surface of the protruding portion.

19. The mobile device of claim 15, wherein:
the hole is a first hole;
the rear cover assembly further comprises a second hole extending through the protruding portion; and
a camera assembly is at least partially positioned within the second hole.

20. The mobile device of claim 19, wherein:
the camera assembly is a first camera assembly;
the rear cover assembly further defines:
a third hole extending through the protruding portion; and
a fourth hole extending through the protruding portion;
a second camera assembly is at least partially positioned within the third hole; and
an optical flash is at least partially positioned within the fourth hole.
